(19) United States
(12) Patent Application Publication
(10) Pub. No.: US 2010/0254079 A1
(43) Pub. Date: Oct. 7, 2010

(54) USB flash drive with improved structure

(76) Inventor: Chieh-yu Cheng, Lu Jhou City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/385,335

(22) Filed: Apr. 6, 2009

(51) Int. Cl. H05K 7/00

(52) U.S. Cl. 361/679.31

(57) ABSTRACT

A USB flash drive with an improved structure includes a housing formed internally with a groove, and a moving case that is movable inside the groove. The groove has a top surface formed with an opening for a movable locking button of the moving case to move therein. In addition, the opening of the housing has two lateral edges whose undersides are concavely provided with plural pairs of engaging recesses to be engaged with projections of the movable locking button.

### BACKGROUND OF THE INVENTION

1. Technical Field

The present invention relates to USB flash drives and, more particularly, to a USB flash drive with an improved structure.

2. Description of Related Art

As computer technology continuously improves and evolves, computer peripherals are also enhanced in design so as to have increased efficiency and reduced volume for high portability.

Among the various computer peripherals, USB flash drives are portable storage devices featuring small volumes and yet large storage capacities. Referring to FIG. 1, the structure of a commercially available USB flash drive includes a housing 10 formed internally with a cavity that opens at both ends of the housing 10. A slot 102 is formed on a top surface of the housing 10 and has two lateral edges concavely provided with two pairs of locking notches 101. A moving case 20 coupled with an USB flash memory 30 is inserted into one of the two ends of the housing 10 and is allowed to move back and forth inside the housing 10. The end of the housing 10 that receives the moving case 20 is further inserted by a rear cover 31 secured in place with glue so as to prevent the moving case 20 from escaping the housing 10.

In addition, a resiliently movable pushbutton 201 with a step-like surface is protrudingly provided on a top surface of the moving case 20 and bilaterally provided with protruding blocks 202 for engaging with a corresponding pair of the locking notches 101 of the slot 102. When the movable pushbutton 201 is pressed downward, the two protruding blocks 202 are disengaged from the corresponding pair of the locking notches 101 so that the moving case 20 can be shifted inside the housing 10 to a different predetermined position. When the downward pressing force applied to the pushbutton 201 is subsequently released, the pushbutton 201 automatically and resiliently recovers, and in consequence the protruding blocks 202 bilaterally provided on the pushbutton 201 are engaged with the other pair of the locking notches 101, thereby securing the moving case 20 in place.

However, there are as many as four components in the conventional USB flash drive structure, and a gluing process is required after the rear cover 30 is inserted into the end of the housing 10. As a result, production of a USB flash drive with the conventional structure is both labor-intensive and time-consuming, not to mention the high costs of molds. Besides, the final products do not provide an integrated appearance.

### BRIEF SUMMARY OF THE INVENTION

In view of the aforesaid shortcomings of the conventional USB flash drive structure, the inventor of the present invention put years of experience in the related industry into simplifying the components of a USB flash drive so as to reduce cost and save labor during production. After extensive research and repeated trials, a compact structure for a USB flash drive is finally obtained and disclosed herein.

The present invention relates to a USB flash drive with an improved structure, wherein the USB flash drive includes a housing formed internally with a groove, and a moving case that is movable inside the groove. A top surface of the groove is formed with an opening for a movable locking button of the moving case to move therein. Besides, the opening of the housing has two lateral edges whose undersides are concavely provided with plural pairs of engaging recesses to be engaged with projections of the movable locking button.

The primary objective of the present invention is to simplify the components of a USB flash drive so that the labor required in assembly and the number of molds are both reduced, thereby lowering related costs.

### BRIEF DESCRIPTION OF THE SEVERAL VIEWS OF THE DRAWINGS

The invention as well as a preferred mode of use, further objectives, and advantages thereof will be best understood by referring to the following detailed description of an illustrative embodiment in conjunction with the accompanying drawings, wherein:

FIG. 1 is an exploded perspective view of a USB flash drive with a conventional structure;

FIG. 2 is a step-by-step illustration of how to assemble a USB flash drive with an improved structure according to the present invention;

FIG. 3 is a cut-away view taken along Line A-A of FIG. 2; and

FIG. 4 is another step-by-step illustration showing assembly of the USB flash drive with the improved structure according to the present invention.

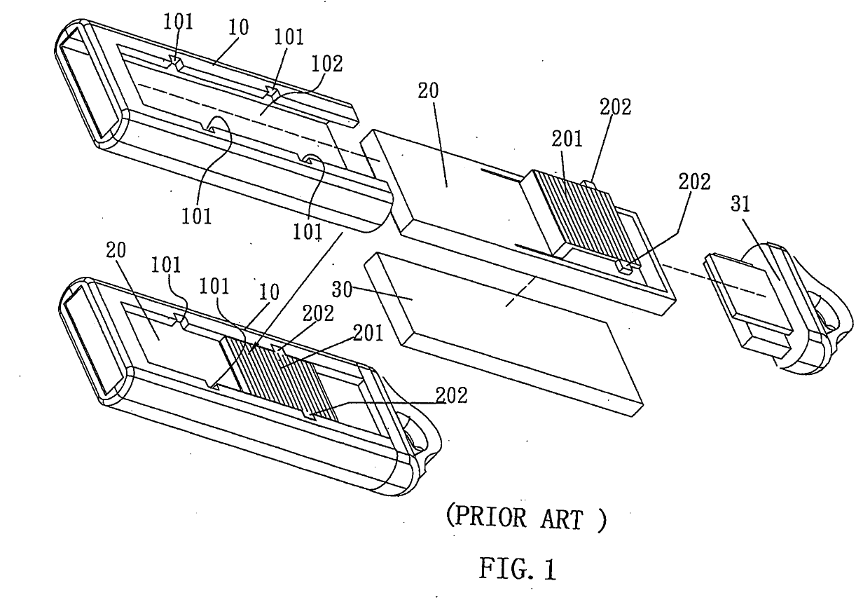

### DETAILED DESCRIPTION OF THE INVENTION

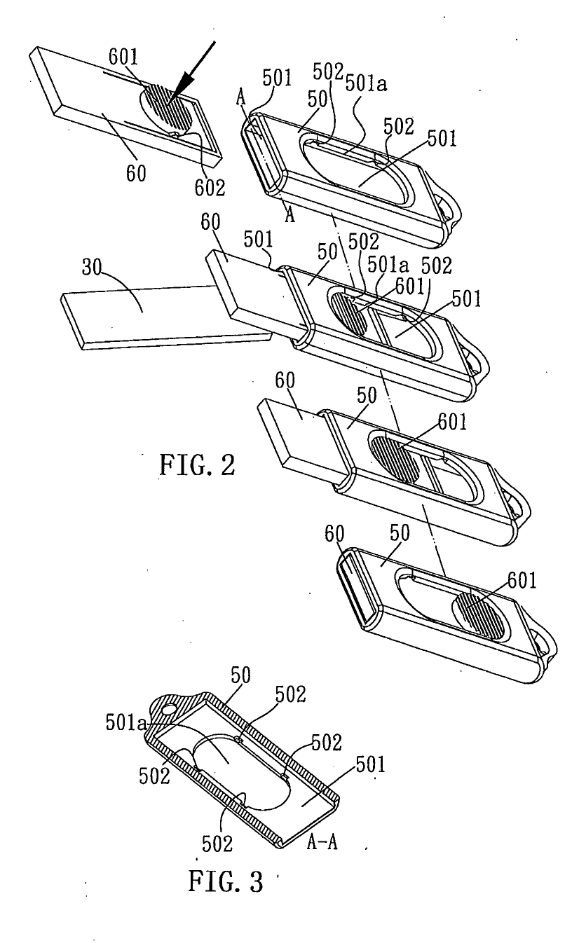

Referring to FIG. 2, a USB flash drive with an improved structure according to the present invention includes a housing 50 and a moving case 60.

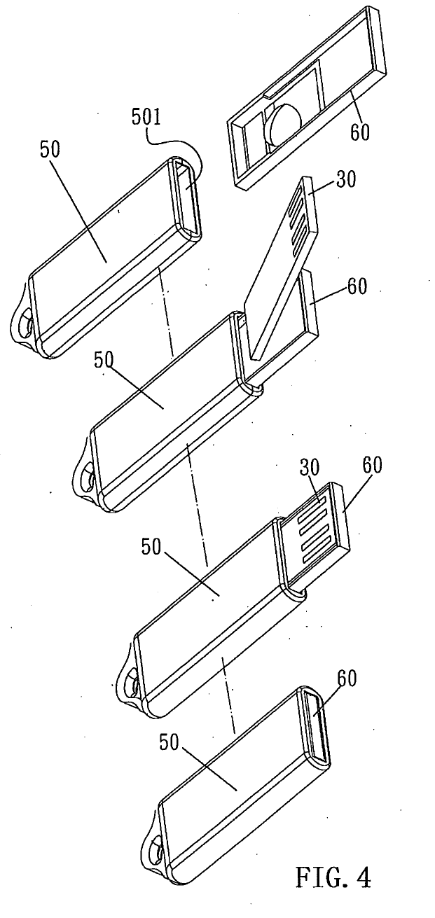

The housing 50 is internally formed with a groove 501. As shown more clearly in FIG. 3, the groove 501 has a top surface formed with an opening 501a. The opening 501a of the housing 50 has two lateral edges whose undersides are concavely provided with plural spaced pairs of engaging recesses 502.

The moving case 60 has a bottom formed with a cavity for receiving a USB flash memory 30. Also, the moving case 60 has a top surface formed with a movable locking button 601, which is bilaterally and protrudingly provided with projections 602.

Referring to FIG. 2 and FIG. 4 for step-by-step illustrations showing how to assemble the USB flash drive with the improved structure of the present invention. To begin with, the movable locking button 601 of the moving case 60 is pressed downward so as to insert the moving case 60 into the groove 501 of the housing 50. Then, the USB flash memory 30 is inserted slantingly into the cavity at the bottom of the moving case 60 so as to be coupled with and secured in position to the moving case 60. Next, the moving case 60 is pushed completely into the groove 501 of the housing 50 so that the moving case 60 can move back and forth inside the groove 501 while the movable locking button 601 of the moving case 60 moves inside the opening 501a of the housing 50. When the moving case 60 is moved to a predetermined position, the projections 602 bilaterally provided on the movable locking button 601 are engaged with a corresponding pair of the engaging recesses 502 of the housing 50 so as to secure the moving case 60 in place.

When the movable locking button 601 of the moving case 60 is pressed downward again, the projections 602 bilaterally provided on the movable locking button 601 are disengaged from the corresponding pair of the engaging recesses 502 of the housing 50, thus allowing the moving case 60 to move simultaneously with the USB flash memory 30 to a different predetermined position. As soon as the downward pressing force applied to the movable locking button 601 is removed, the movable locking button 601 automatically recovers so that the projections 602 bilaterally provided on the movable locking button 601 are engaged with another pair of the engaging recesses 502 of the housing 50, thereby securing the moving case 60 in position.

In short, the present invention achieves the intended effects and has never been put to public use. Thus, the present invention meets the requirements of utility and novelty for patent application, and an application for patent protection of the present invention is hereby lawfully filed for examination.

It should be noted that the present invention is herein demonstrated by reference to the preferred embodiment. All changes or modifications which are based on the concept of the present invention and whose functions and effects do not depart from the spirit of the present invention should be encompassed by the appended claims.

1. A USB flash drive with an improved structure, characterized by comprising:
a housing formed internally with a groove, the groove having a top surface formed with an opening having two lateral edges whose undersides are concavely provided with plural spaced pairs of engaging recesses; and
a moving case having a bottom formed with a cavity for receiving a USB flash memory, the moving case further having a top surface formed with a movable locking button bilaterally and protrudingly provided with projections;
wherein the USB flash drive is assembled by pressing down the movable locking button of the moving case so as to insert the moving case into the groove of the housing, then inserting the USB flash memory slantingly into the cavity at the bottom of the moving case so that the USB flash memory is coupled with and secured in position to the moving case, and finally pushing the moving case completely into the groove of the housing so that the moving case is movable back and forth inside the groove of the housing while the movable locking button of the moving case moves in the opening of the housing, the moving case being secured at a predetermined position upon engagement of the projections bilaterally provided on the movable locking button with a corresponding pair of the engaging recesses of the housing, wherein when an external force is applied to and thereby presses down the movable locking button of the moving case, the projections bilaterally provided on the movable locking button are disengaged from the corresponding pair of the engaging recesses of the housing so that the moving case can be moved simultaneously with the USB flash memory to another predetermined position, and, upon releasing the external force pressing down the movable locking button, the movable locking button automatically and resiliently recovers so that the projections bilaterally provided on the movable locking button are engaged with another pair of the engaging recesses of the housing, thereby securing the moving case in position.
